(19) United States
(12) Patent Application Publication
(10) Pub. No.: US 2026/0108903 A1
(43) Pub. Date: Apr. 23, 2026

(54) MASK FOR DEPOSITION AND DISPLAY SYSTEM MANUFACTURED BY THE SAME

(71) Applicant: Samsung Display Co., Ltd., Yongin-si (KR)

(72) Inventors: Jeong Kuk KIM, Yongin-si (KR); Young Jin SONG, Yongin-si (KR); Yeon Woo LEE, Yongin-si (KR); Ji Hyun JUNG, Yongin-si (KR); Jun Ho JO, Yongin-si (KR)

(73) Assignee: Samsung Display Co., Ltd., Yongin-si (KR)

(21) Appl. No.: 19/256,569

(22) Filed: Jul. 1, 2025

(30) Foreign Application Priority Data
Oct. 18, 2024 (KR) 10-2024-0143154

(51) Int. Cl. B05B 12/20; H10K 59/10

(52) U.S. Cl. CPC B05B 12/20; H10K 59/10

(57) ABSTRACT

A mask for deposition, which includes a deposition area and a non-deposition area, includes a wafer substrate including a plurality of first openings spaced apart from each other, an inorganic layer disposed on the wafer substrate and including a plurality of second openings each overlapping with a corresponding one of the plurality of first openings in a plan view, a pattern layer disposed on the inorganic layer, doped with an impurity to have an electrical conductivity, and at least one electrode terminal electrically connected to the pattern layer to apply an external voltage to the pattern layer. The wafer substrate and the inorganic layer are formed in the deposition area and the non-deposition area, the pattern layer is formed in the deposition area, and the at least one electrode terminal is formed in the non-deposition area.

### CROSS-REFERENCE TO RELATED APPLICATION(S)

This application claims priority to and benefits of Korean Patent Application No. 10-2024-0143154 under 35 U.S.C. § 119, filed Oct. 18, 2024, in the Korean Intellectual Property Office (KIPO), the entire contents of which are incorporated herein by reference.

### BACKGROUND

### 1. Technical Field

This application generally relates to a mask for deposition and a display system manufactured by the same.

### 2. Description of the Related Art

With the development of multimedia, the importance of display devices has increased. Accordingly, various types of display devices such as an organic light emitting display device and a liquid crystal display device are used.

For example, organic light emitting display devices may be used for mobile devices such as a smartphone, a computer, and a tablet personal computer or electronic devices such as a television, an outdoor billboard, and a display for exhibition.

An organic light emitting display device may include an anode electrode, a cathode electrode, and an organic light emitting layer interposed between the anode electrode and the cathode electrode, which are disposed on a substrate. The organic light emitting layer may be formed using a mask for deposition.

The above information disclosed in this Related Art section is only for enhancement of understanding of the background of the disclosure and therefore it may contain information that does not form the prior art that is already known in this country to a person of ordinary skill in the art.

### SUMMARY

Embodiments of this application provide a mask for deposition, which can improve adhesion with a substrate, and a display system manufactured by the mask.

In accordance with an embodiment of the disclosure, a mask for deposition, which includes a deposition area and a non-deposition area, may include a wafer substrate including a plurality of first openings spaced apart from each other, an inorganic layer disposed on the wafer substrate and including a plurality of second openings each overlapping with a corresponding one of the plurality of first openings in a plan view, a pattern layer disposed on the inorganic layer, doped with an impurity to have an electrical conductivity, and including a plurality of third openings overlapping one of the plurality of first openings and one of the plurality of second openings, which overlap with each other in a plan view, and at least one electrode terminal electrically connected to the pattern layer to apply an external voltage to the pattern layer. The wafer substrate and the inorganic layer may be formed in the deposition area and the non-deposition area, the pattern layer may be formed in the deposition area, and the at least one electrode terminal may be formed in the non-deposition area.

The wafer substrate may include monocrystalline or polycrystalline silicon.

The inorganic layer may include at least one of silicon oxide (SiOₓ), silicon nitride (SiNₓ), and silicon oxynitride (SiOₓN_{y}), x may be a rational number, and y may be another rational number.

The pattern layer may include at least one of silicon (Si), silicon oxide (SiOₓ), silicon nitride (SiNₓ), and silicon oxynitride (SiOₓN_{y}), x may be a rational number, and y may be another rational number.

The at least one electrode terminal may be made of a material having an electrical conductivity.

The at least one electrode terminal and the pattern layer may be made of a substantially same material.

One of the plurality of first openings, one of the plurality of second openings, and the plurality of third openings, which overlap each other in a plan view, may form a cell opening area. The cell opening area may define a display area of a display panel.

The pattern layer may be formed as one body in an entire area of the deposition area.

The mask may further include an insulating layer disposed on the pattern layer in the deposition area, disposed on the inorganic layer in the non-deposition area, and including a plurality of fourth openings each overlapping with a corresponding one of the plurality of third openings in a plan view.

An entire top surface of the insulating layer, which faces a substrate on which a deposition material is deposited, may be formed substantially flat.

The insulating layer may include at least one of an inorganic insulating material and an organic insulating material.

The pattern layer may include at least one first pattern layer electrically connected to the at least one electrode terminal, a plurality of second pattern layers spaced apart from the at least one first pattern layer in a first direction, a plurality of third pattern layers spaced apart from the at least one first pattern layer in a second direction intersecting the first direction, and a plurality of fourth pattern layers spaced apart from one of the plurality of third pattern layers in the first direction. The mask may further include a bridge electrically connecting the at least one first pattern layer to the plurality of second pattern layers, the plurality of third pattern layers, and the plurality of fourth pattern layers.

The external voltage applied to the at least one first pattern layer through the at least one electrode terminal may be applied to the plurality of second pattern layers, the plurality of third pattern layers, and the plurality of fourth pattern layers through the bridge.

The bridge and the pattern layer may be made of a substantially same material.

The bridge may be disposed on the inorganic layer between adjacent ones of the at least one first pattern layer, the plurality of second pattern layers, the plurality of third pattern layers, and the plurality of fourth pattern layers.

The bridge may include: a plurality of first bridges electrically connecting, to each other, the at least one first pattern layer and at least one of the plurality of second pattern layers, which are arranged in the first direction, and at least one of the plurality of third pattern layers and at least one of the plurality of fourth pattern layers, which are arranged in the first direction; and a plurality of second bridges electrically connecting, to each other, the at least one first pattern layer and at least one of the plurality of third pattern layers, which are arranged in the second direction, and at least one of the plurality of second pattern layers and at least one of the plurality of fourth pattern layers, which are arranged in the second direction.

The mask may further include an insulating layer disposed on the at least one first pattern layer, the plurality of second pattern layers, the plurality of third pattern layers, and the plurality of fourth pattern layers, a portion of the inorganic layer, which is disposed between the at least one first pattern layer, the plurality of second pattern layers, the plurality of third pattern layers, and the plurality of fourth pattern layers, and the bridge in the deposition area, disposed on another portion of the inorganic layer in the non-deposition area, and including a plurality of fourth openings each overlapping with a corresponding one of the plurality of third openings in a plan view.

An entire top surface of the insulating layer, which faces a substrate on which a deposition material is deposited, may be formed substantially flat.

In accordance with an embodiment of the disclosure, a display system may include an organic light emitting layer disposed between a cathode electrode and an anode electrode. The organic light emitting layer may be formed by the mask.

### BRIEF DESCRIPTION OF THE DRAWINGS

Embodiments will now be described more fully hereinafter with reference to the accompanying drawings; however, they may be embodied in different forms and should not be construed as limited to the embodiments set forth herein. Rather, these embodiments are provided so that this disclosure will be more thorough and complete, and will fully convey the scope of the embodiments to those skilled in the art.

In the drawing figures, dimensions may be exaggerated for clarity of illustration. It will be understood that when an element is referred to as being “between” two elements, it can be the only element between the two elements, or one or more intervening elements may also be present. Like reference numerals refer to like elements throughout.

FIG. 1 is a plan view illustrating an embodiment of a mask for deposition.

FIG. 2 is a schematic cross-sectional view taken along line I-I′ shown in FIG. 1.

FIG. 3 is a schematic diagram illustrating a pixel formed using the mask for deposition in accordance with embodiments of the disclosure.

FIG. 4 is a schematic cross-sectional view illustrating a display panel including the pixel shown in FIG. 3.

FIG. 5 is a schematic cross-sectional view illustrating a process of manufacturing the display panel shown in FIG. 4, using the mask for deposition, which is shown in FIG. 1.

FIG. 6 is a plan view illustrating another embodiment of the mask for deposition.

FIG. 7 is a schematic-cross sectional view taken along line II-II′ shown in FIG. 6.

FIG. 8 is a plan view illustrating still another embodiment of the mask for deposition.

FIG. 9 is an enlarged plan view of area AA shown in FIG. 8.

FIG. 10 is a schematic cross-sectional view taken along line III-III′ shown in FIG. 9.

FIG. 11 is a schematic cross-sectional view taken along line IV-IV′ shown in FIG. 9.

FIG. 12 is a schematic cross-sectional view illustrating another embodiment of FIG. 10.

FIG. 13 is a schematic cross-sectional view illustrating another embodiment of FIG. 11.

FIG. 14 is a schematic block diagram illustrating an embodiment of a display system.

FIGS. 15 to 18 are perspective views illustrating application examples of the display system shown in FIG. 14.

### DETAILED DESCRIPTION OF THE EMBODIMENTS

Hereinafter, embodiments of the disclosure will be described in more detail with reference to the accompanying drawings. In the description below, only a part to understand an operation according to the disclosure is described and the descriptions of other parts are omitted in order not to unnecessarily obscure subject matters of the disclosure. In addition, the disclosure is not limited to embodiments described herein, but may be embodied in various different forms. Rather, embodiments described herein are provided to thoroughly and completely describe the disclosed contents and to sufficiently transfer the ideas of the disclosure to a person of ordinary skill in the art.

When an element, such as a layer, is referred to as being “on,” “connected to,” or “coupled to” another element or layer, it may be directly on, connected to, or coupled to the other element or layer or intervening elements or layers may be present. When, however, an element or layer is referred to as being “directly on,” “directly connected to,” or “directly coupled to” another element or layer, there are no intervening elements or layers present. To this end, the term “connected” may refer to physical, electrical, and/or fluid connection, with or without intervening elements. Also, when an element is referred to as being “in contact” or “contacted” or the like to another element, the element may be in “electrical contact” or in “physical contact” with another element; or in “indirect contact” or in “direct contact” with another element.

The technical terms used herein are used only for the purpose of illustrating a specific embodiment and not intended to limit the embodiment. The terminology used herein is for the purpose of describing particular embodiments and is not intended to be limiting. As used herein, the singular forms, “a,” “an,” and “the” are intended to include the plural forms as well, unless the context clearly indicates otherwise. Moreover, the terms “comprises,” “comprising,” “includes,” and/or “including,” when used in this specification, specify the presence of stated features, integers, steps, operations, elements, components, and/or groups thereof, but do not preclude the presence or addition of one or more other features, integers, steps, operations, elements, components, and/or groups thereof.

In the specification and the claims, the phrase “at least one of” is intended to include the meaning of “at least one selected from the group of” for the purpose of its meaning and interpretation. For example, “at least one of A and B” may be understood to mean “A, B, or A and B.” In the specification and the claims, the term “and/or” is intended to include any combination of the terms “and” and “or” for the purpose of its meaning and interpretation. For example, “A and/or B” may be understood to mean “A, B, or A and B.” The terms “and” and “or” may be used in the conjunctive or disjunctive sense and may be understood to be equivalent to “and/or.”

It will be understood that, although the terms “first”, “second,” etc. may be used herein to describe various elements, these elements should not be limited by these terms. These terms are only used to distinguish one element from another element. Thus, a “first” element discussed below could also be termed a “second” element without departing from the teachings of the disclosure.

Spatially relative terms, such as “below,” “above,” and the like, may be used herein for ease of description to describe the relationship of one element to another element, as illustrated in the figures. It will be understood that the spatially relative terms, as well as the illustrated configurations, are intended to encompass different orientations of the apparatus in use or operation in addition to the orientations described herein and depicted in the figures. For example, if the apparatus in the figures is turned over, elements described as “below” or “beneath” other elements or features would be oriented “above” the other elements or features. Thus, the term, “above,” may encompass both an orientation of above and below. The apparatus may be otherwise oriented (e.g., rotated 90 degrees or at other orientations) and the spatially relative descriptors used herein interpreted accordingly.

In addition, the embodiments of the disclosure are described here with reference to schematic diagrams of embodiments (and an intermediate structure) of the disclosure, so that changes in a shape as shown due to, for example, manufacturing technology and/or a tolerance may be expected. Therefore, the embodiments of the disclosure shall not be limited to the specific shapes of a region shown here, but include shape deviations caused by, for example, the manufacturing technology. The regions shown in the drawings are schematic in nature, and the shapes thereof do not represent the actual shapes of the regions of the device, and do not limit the scope of the disclosure.

Unless otherwise defined or implied herein, all terms (including technical and scientific terms) used have the same meaning as commonly understood by those skilled in the art to which this disclosure pertains. It will be further understood that terms, such as those defined in commonly used dictionaries, should be interpreted as having a meaning that is consistent with their meaning in the context of the relevant art and should not be interpreted in an ideal or excessively formal sense unless clearly defined in the specification.

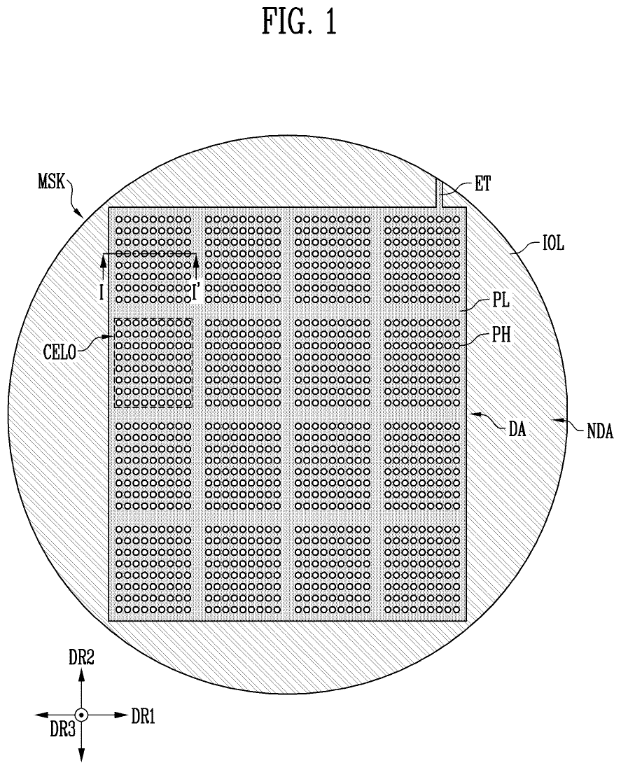

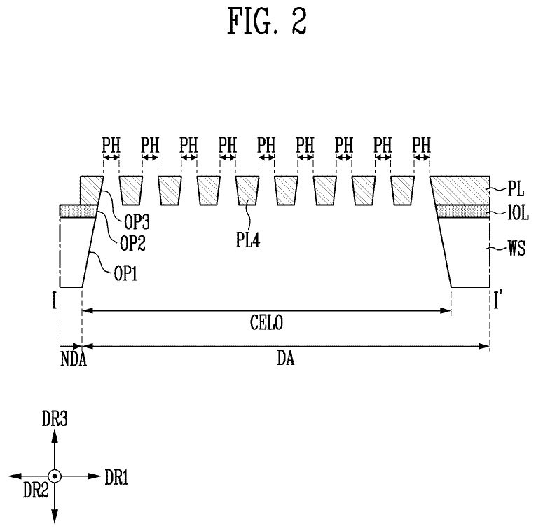

FIG. 1 is a plan view illustrating an embodiment of a mask for deposition. FIG. 2 is a schematic cross-sectional view taken along line I-I′ shown in FIG. 1.

Referring to FIGS. 1 and 2, a mask MSK for deposition in accordance with an embodiment of the disclosure may include a wafer substrate WS, an inorganic layer IOL, a pattern layer PL, and an electrode terminal ET.

The mask MSK for deposition may be an apparatus used in a deposition process so as to deposit a deposition material in a target area of a deposition target object, and may include multiple pattern holes PH which allow the deposition material to pass through. The pattern holes PH may be arranged in a regular pattern on a plane formed by a first direction DR1 and a second direction DR2 (hereinafter, referred to as “a plane”), and a specific number of pattern holes PH may be defined as one cell opening area CELO. Multiple cell opening areas CELO may be arranged side by side in each of the first and second directions DR1 and DR2 on a plane and spaced apart from each other.

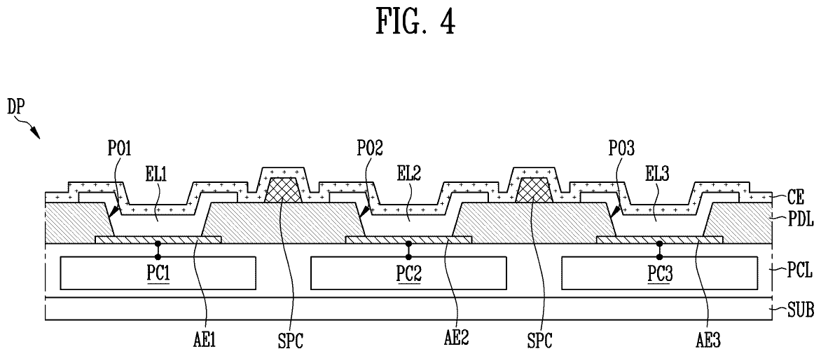

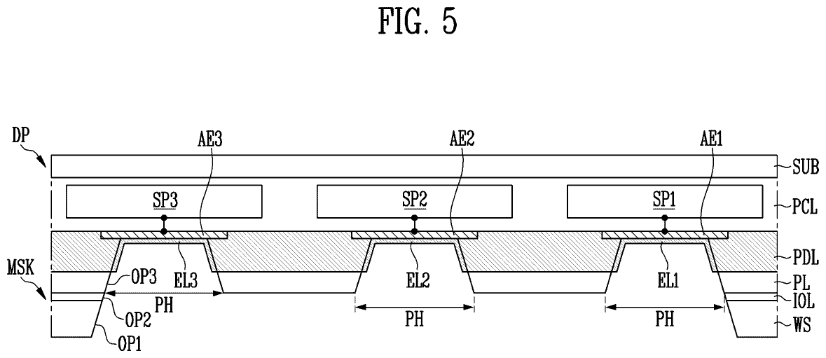

Each of the cell opening areas CELO may correspond one-to-one to a deposition target object. For example, one cell opening area CELO may define a display area of one display panel (see DP shown in FIG. 4). According to this structure, a deposition process may be simultaneously performed on multiple deposition target objects, using one mask MSK for deposition. For example, in a deposition process, the mask MSK for deposition may be aligned to face a deposition target object (e.g., DP shown in FIG. 5).

As described above, the mask MSK for deposition may allow the deposition material to pass through the cell opening area CELO, and block the deposition material in an area other than the cell opening area CELO. Accordingly, the deposition material may be selectively deposited in only a specific area of a deposition target overlapping the cell opening area CELO (e.g., a display area of a display panel) in a third direction DR3. Therefore, for convenience of description, a partial area of the mask MSK for deposition, in which multiple cell opening areas CELO are grouped will be referred to as a deposition area DA, and the area other than the cell opening areas CELO will be referred to as a non-deposition area NDA.

The wafer substrate WS may be a component serving as an overall frame of the mask MSK for deposition, and may be formed in the deposition area DA and the non-deposition area NDA. The wafer substrate WS may have a circular shape in a plan view, and be made of a crystalline silicon material such as monocrystalline or polycrystalline silicon. However, the material and shape constituting the wafer substrate WS are not limited thereto. For example, the wafer substrate WS may be made of various materials, and have various shapes in a plan view.

The wafer substrate WS may include multiple first openings OP1 spaced apart from each other. The first openings OP1 may overlap the cell opening areas CELO of the mask MSK for deposition in a third direction DR3. In other words, the first openings OP1 may be formed in the deposition area DA. Therefore, like the cell opening areas CELO, the first openings OP1 may be arranged in a regular pattern in the first and second directions DR1 and DR2, and one first opening OP1 among the first openings OP1 may overlap a specific number of pattern holes PH in the third direction DR3. For example, referring to FIG. 1, four cell opening areas CELO along the first direction DR1 and four cell opening areas CELO along the second direction DR2 may be formed, and hence four first openings OP1 along the first direction DR1 and four first openings OP1 along the second direction DR2 may also be formed.

In embodiments, an inner surface of the wafer substrate WS, which surrounds each of the first openings OP1, may have a tapered shape in a cross-sectional view. This may be because the first openings OP1 are formed by wet-etching the wafer substrate WS, but the disclosure is not necessarily limited thereto.

The inorganic layer IOL may be disposed between the wafer substrate WS and the pattern layer PL which will be described below, and be formed in the deposition area DA and the non-deposition area NDA, like the wafer substrate WS. The inorganic layer IOL may also have a circular shape in a plan view, like the wafer substrate WS, and include an inorganic material. For example, the inorganic layer IOL may include at least one of silicon oxide (SiOₓ), silicon nitride (SiNₓ), and silicon oxynitride (SiOₓN_{y}).

The inorganic layer IOL may be formed on the wafer substrate WS, and include multiple second openings OP2 overlapping the first openings OP1 in the third direction DR3. In embodiments, an inner surface of the inorganic layer IOL, which surrounds each of the second openings OP2, may have a tapered shape in a cross-sectional view, like the inner surface of the wafer substrate WS, which surrounds each of the first openings OP1. This may be because the second openings OP2 are formed by wet-etching the inorganic layer IOL, but the disclosure is not necessarily limited thereto.

In embodiments, a longest width of a second opening OP2 may be smaller than a longest width of a first opening OP1 overlapping the second opening OP2 in the third direction DR3. In embodiments, a shortest width of a first opening OP1 may be substantially equal to a longest width of a second opening OP2 overlapping the first opening OP1 in the third direction DR3. This means that inner surfaces of a first opening OP1 and a second opening OP2, which overlap each other in the third direction DR3, may be successively connected to each other.

The pattern layer PL may be a component including multiple cell opening areas CELO and multiple pattern holes PH formed in each of the cell opening areas CELO, and may be formed in the deposition area DA. Referring to FIGS. 1 and 2, the pattern layer PL may be formed in one body to overlap the entire deposition area DA in the third direction DR3.

The pattern layer PL may include at least one of silicon (Si), silicon oxide (SiOₓ), silicon nitride (SiNₓ), and silicon oxynitride (SiOₓN_{y}). In embodiments, an impurity may be doped into the pattern layer PL such that the pattern layer PL has an electrical conductivity. For example, in case that a Group V element such as phosphorus (P), arsenic (As) or antimony (Sb) is doped into the pattern layer PL, the pattern layer PL may have an n-type semiconductor characteristic. For example, in case that a Group III element such as boron (B), gallium (Ga) or indium (In) is doped into the pattern layer PL, the pattern layer PL may have a p-type semiconductor characteristic.

The pattern layer PL may include multiple third openings OP3 overlapping one of the openings OP1 and one of the second openings OP2, which overlap with each other in the third direction DR3. In embodiments, an inner surface of the pattern layer PL, which surrounds some third openings OP3 disposed at an outermost portion among third openings OP3 overlapping one cell opening area CELO, may have a tapered shape, like the inner surface of the inorganic layer IOL, which surrounds each of the second openings OP2, and the inner surface of the inorganic layer IOL, which surrounds each of the second openings OP2, and the inner surface of the pattern layer PL, which surrounds some third openings OP3 disposed at an outermost portion among third openings OP3 overlapping one cell opening area CELO, may be successively connected to each other.

As such, multiple third openings OP3, and one second opening OP2 and one first opening OP1, which overlap the third openings OP3, may be provided in one cell opening area CELO. According to this structure, a deposition material evaporated or sprayed toward the mask MSK for deposition may enter through a first opening OP1 and sequentially pass through a second opening OP2 and a third opening OP3. A passing path of the deposition material, which is formed by the first to third openings OP1, OP2, and OP3 overlapping each other as described above, may be defined as one pattern hole PH.

The electrode terminal ET may be electrically connected to the pattern layer PL to apply an external voltage to the pattern layer PL. To this end, the electrode terminal ET may be made of a material having an electrical conductivity, such as a metal, but the disclosure is not necessarily limited thereto. In embodiments, the electrode terminal ET may be formed with the pattern layer PL through a same process. Therefore, the electrode terminal ET and the pattern layer PL may be made of a substantially same material. For example, the electrode terminal ET may include at least one of silicon (Si), silicon oxide (SiOₓ), silicon nitride (SiNₓ), and silicon oxynitride (SiOₓN_{y}). An impurity may be doped into the electrode terminal ET such that the electrode terminal ET has an electrical conductivity. For example, in case that a Group V element such as phosphorus (P), arsenic (As) or antimony (Sb) is doped into the electrode terminal ET, the electrode terminal ET may have an n-type semiconductor characteristic. For example, in case that a Group III element such as boron (B), gallium (Ga) or indium (In) is doped into the electrode terminal ET, the electrode terminal ET may have a p-type semiconductor characteristic.

In embodiments, the electrode terminal ET may be formed in the non-deposition area NDA, and extend in a direction toward an edge of the mask MSK for deposition from a portion of the pattern layer PL.

According to this structure, the external voltage applied to the electrode terminal ET may be applied to the entire pattern layer PL electrically connected to the electrode terminal ET. This is because the pattern layer PL has a structure in which the pattern layer PL is formed as one body. In case that a positive or negative voltage is applied to the electrode terminal ET during a deposition process, the pattern layer PL and the voltage applied to the electrode terminal ET may have a same polarity. During a deposition process, a substrate (see SUB shown in FIG. 5) of the display panel (see DP shown in FIG. 5), which faces the pattern layer PL, may have a polarity opposite to the polarity of the voltage applied to the electrode terminal ET, and accordingly, an attractive force with which the mask MSK for deposition and the substrate SUB of the display panel DP pull each other may act between the mask MSK for deposition and the substrate SUB of the display panel DP. Thus, a gap between the mask MSK for deposition and the display panel DP may be minimized by the attractive force generated between the mask MSK for deposition and the substrate SUB of the display panel DP, and accordingly, the deposition precision of the deposition material may be improved. Further, the defect rate of the display panel DP may be reduced.

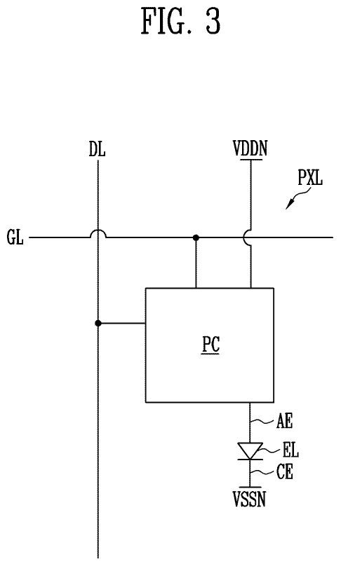

Hereinafter, a pixel formed using the mask MSK for deposition and a display panel including the pixel will be described with reference to FIGS. 3 and 4.

FIG. 3 is a schematic diagram illustrating a pixel formed using the mask for deposition in accordance with embodiments of the disclosure.

Referring to FIG. 3, a pixel PXL may include a pixel circuit PC and an organic light emitting layer EL.

The pixel circuit PC may be connected to a gate line GL and a data line DL. The pixel circuit PC may control the organic light emitting layer EL in response to a gate signal received through the gate line GL, thereby emitting light according to a data signal received through the data line DL. For these operations, the pixel circuit PC may include circuit elements, e.g., transistors and one or more capacitors.

The organic light emitting layer EL may be connected between a first power voltage node VDDN and a second power voltage node VSSN. The first power voltage node VDDN may receive a first power voltage. The second power voltage node VSSN may receive a second power voltage. The first power voltage may have a voltage level higher than a voltage level of the second power voltage.

The organic light emitting layer EL may be connected between an anode electrode AE and a cathode electrode CE. The anode electrode AE may be connected to the first power voltage node VDDN through the pixel circuit PC. For example, the anode electrode AE may be connected to the first power voltage node VDDL through one or more transistors included in the pixel circuit PC. The cathode electrode CE may be connected to the second power voltage node VSSN. The organic light emitting layer EL may be configured to emit light according to a current flow from the anode electrode AE to the cathode electrode CE.

FIG. 4 is a schematic cross-sectional view illustrating a display panel including the pixel shown in FIG. 3.

Referring to FIG. 4, a display panel DP may include a substrate SUB, a pixel circuit layer PCL, first to third anode electrodes AE1, AE2, and AE3, first to third organic light emitting layers EL1, EL2, and EL3, a pixel defining layer PDL, and a cathode electrode CE.

The substrate SUB may be made of an insulative material such as glass or a resin. For example, the substrate SUB may include a glass substrate. In another embodiment, the substrate SUB may include a polyimide substrate. In another embodiment, the substrate SUB may include a silicon wafer substrate formed using a semiconductor process.

The pixel circuit layer PCL may be disposed on the substrate SUB. The pixel circuit layer PCL may include insulating layers, and semiconductor patterns and conductive patterns, which are disposed between the insulating layers. The conductive patterns of the pixel circuit layer PCL may serve as circuit elements, lines, and the like. The circuit elements of the pixel circuit layer PCL may define first to third pixel circuits PC1, PC2, and PC3. Each of the first to third pixel circuits PC1, PC2, and PC3 may be connected to the gate line GL, the data line DL, and the first power voltage node VDDN, which are shown in FIG. 3.

The first to third anode electrodes AE1, AE2, and AE3 may be disposed on the pixel circuit layer PCL. The first anode electrode AE1 may be connected to the first pixel circuit PC1. The second anode electrode AE2 may be connected to the second pixel circuit PC2. The third anode electrode AE3 may be connected to the third pixel circuit PC3.

The pixel defining layer PDL may be disposed on the pixel circuit layer PCL and the first to third anode electrodes AE1, AE2, and AE3. The pixel defining layer PDL may include first to third pixel openings PO1, PO2, and PO3 exposing a portion of each of the first to third anode electrodes AE1, AE2, and AE3. The pixel defining layer PDL may include a light blocking material, to prevent light mixture between adjacent pixels. In embodiments, the pixel defining layer PDL may include an organic material. For example, the pixel defining layer PDL may include an organic insulating material such as an acrylic resin, an epoxy resin, a phenolic resin, a polyamide resin, or a polyimide resin. A spacer SPC may be disposed on a portion of the pixel defining layer PDL.

The first organic light emitting layer EL1 may be disposed on a portion of the first anode electrode AE1 exposed by the first pixel opening PO1 and a side surface of the pixel defining layer PDL, which is adjacent to the first anode electrode AE1. The second organic light emitting layer EL2 may be disposed on a portion of the second anode electrode AE2 exposed by the second pixel opening PO2 and a side surface of the pixel defining layer PDL, which is adjacent to the second anode electrode AE2. The third organic light emitting layer EL3 may be disposed on a portion of the third anode electrode AE3 exposed by the third pixel opening PO3 and a side surface of the pixel defining layer PDL, which is adjacent to the third anode electrode AE3. The first to third organic light emitting layers EL1, EL2, and EL3 may include an organic material capable of emitting light, based on a signal provided from the first to third anode electrodes AE1, AE2, and AE3.

The cathode electrode CE may cover the pixel defining layer PDL and the first to third organic light emitting layers EL1, EL2, and EL3. The cathode electrode CE may be connected to the first to third organic light emitting layers EL1, EL2, and EL3. As such, the cathode electrode CE may be a common electrode commonly provided to the first to third organic light emitting layers EL1, EL2, and EL3. The cathode electrode CE may be connected to the second power voltage node VSSN.

A first pixel may be provided, which includes the first pixel circuit PC1, the first anode electrode AE1, the cathode electrode CE, and the first organic light emitting layer EL1 disposed between the first anode electrode AE1 and the cathode electrode CE. Similarly, a second pixel may be provided, which includes the second pixel circuit PC2, the second anode electrode AE, the cathode electrode CE, and the second organic light emitting layer EL2 disposed between the second anode electrode AE2 and the cathode electrode CE, and a third pixel may be provided, which includes a third pixel circuit PC3, the third anode electrode AE3, the cathode electrode CE, and the third organic light emitting layer EL3 disposed between the third anode electrode AE3 and the cathode electrode CE.

FIG. 5 is a schematic cross-sectional view illustrating a process of manufacturing the display panel shown in FIG. 4, using the mask for deposition, which is shown in FIG. 1.

Referring to FIG. 5, the display panel DP may be provided, which includes the substrate SUB, the pixel circuit layer PCL, the first to third anode electrodes AE1, AE2, and AE3, and a pixel defining layer PDL.

The mask MSK for deposition, which is described with reference to FIGS. 1 and 2, may be disposed to be in contact with or adjacent to the pixel defining layer PDL of the display panel DP while approaching to the display panel DP in a state in which the pattern layer PL is aligned to face the pixel defining layer PDL. The pattern holes PH may expose the first to third pixel openings (see PO1, PO2, and PO3 shown in FIG. 4). Also, although not shown in the drawing, the pattern holes PH may expose portions of the pixel defining layer PDL, which are adjacent to the first to third pixel openings PO1, PO2, and PO3.

In this state, the first to third organic light emitting layers EL1, EL2, and EL3 may be deposited on the first to third pixel openings PO1, PO2, and PO3. Also, although not shown in the drawing, the first to third organic light emitting layers EL1, EL2, and EL3 may also be deposited on portions of the pixel defining layer PDL, which are adjacent to the first to third pixel openings PO1, PO2, and PO3. After that, the mask MSK for deposition may be removed, and the cathode electrode CE which has been described with reference to FIG. 4, may be further formed over the first to third organic light emitting layers EL1, EL2, and EL3.

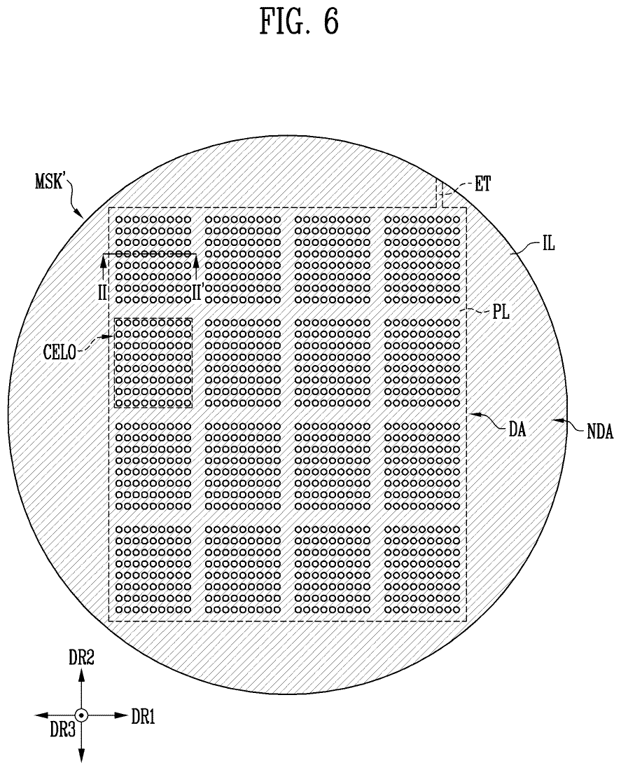

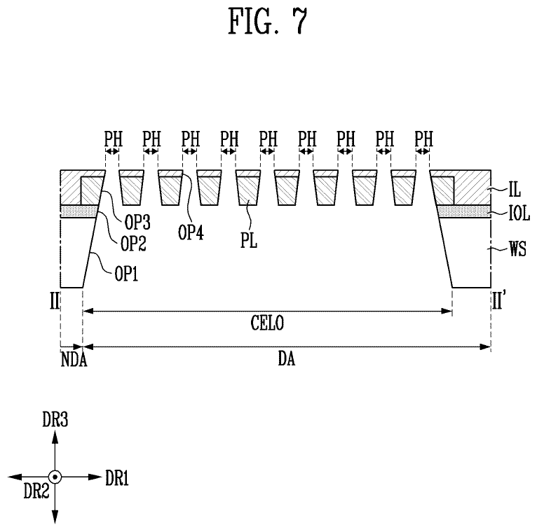

FIG. 6 is a plan view illustrating another embodiment of the mask for deposition. FIG. 7 is a schematic cross-sectional view taken along line II-II′ shown in FIG. 6.

Referring to FIGS. 6 and 7, a mask MSK′ for deposition in accordance with an embodiment of the disclosure may include a wafer substrate WS, an inorganic layer IOL, a pattern layer PL, an electrode terminal ET, and an insulating layer IL.

The components, i.e., the wafer substrate WS, the inorganic layer IOL, the pattern layer PL, and the electrode terminal ET other than the insulating layer IL shown in FIGS. 6 and 7 may be configured identically to the wafer substrate WS, the inorganic layer IOL, the pattern layer PL, and the electrode terminal ET, which are described with reference to FIGS. 1 and 2. Therefore, hereinafter, overlapping descriptions will be omitted for convenience of description.

The insulating layer IL may be disposed on the pattern layer PL in a deposition area DA, and be disposed on the inorganic layer IOL in a non-deposition area NDA. Like the wafer substrate WS and the inorganic layer IOL, the insulating layer IL may have a circular shape in a plan view, and include an insulating material. In embodiments, the insulating layer IL may include at least one of an inorganic insulating material and an organic insulating material. For example, the insulating layer IL may include an inorganic insulating material such as silicon oxide (SiOₓ), silicon nitride (SiNₓ), or silicon oxynitride (SiOₓN_{y}). For example, the insulating layer IL may include an organic insulating material such as an acrylic resin, an epoxy resin, a phenolic resin, a polyamide resin, a polyimide resin, an unsaturated polyester resin, a polyphenylene ether resin, a polyphenylene sulfide resin, or benzocyclobutene (BCB). However, the insulating material constituting the insulating layer IL is not necessarily limited to the above-listed materials.

The insulating layer IL may include multiple fourth openings OP4 overlapping corresponding third openings OP3. In embodiments, an inner surface of the insulating layer IL, which surrounds each of the fourth openings OP4, may have a tapered shape in a cross-sectional view, like an inner surface of the pattern layer PL, which surrounds each of the third openings OP3. This may be because the fourth openings OP4 are formed by wet-etching the insulating layer IL, but the disclosure is not necessarily limited thereto.

In embodiments, a longest width of a fourth opening OP4 may be smaller than a longest width of a third opening OP3 overlapping the fourth opening OP4 in the third direction DR3. In embodiments, a shortest width of a third opening OP3 may be substantially the same as a longest width of a fourth opening OP4 overlapping the third opening OP3 in the third direction DR3. This means that inner surfaces of a third opening OP3 and a fourth opening OP4, which overlap each other in the third direction DR3, may be successively connected to each other.

As such, multiple fourth openings OP4, multiple third openings OP3 overlapping corresponding fourth openings OP4, and one second opening OP2 and a first opening OP1, which overlap the fourth openings OP4 and the third openings OP3, may be provided in one cell opening area CELO. According to this structure, a deposition material evaporated or sprayed toward the mask MSK′ for deposition may enter through a first opening OP1 and sequentially pass through a second opening OP2, a third opening OP3, and a fourth opening OP4. A passing path of the deposition material, which is formed by the first to fourth openings OP1, OP2, OP3, and OP4 overlapping each other as described above, may be defined as one pattern hole PH.

In embodiments, the entire top surface of the insulating layer IL disposed to face the substrate (see SUB shown in FIG. 5) of the display panel (see DP shown in FIG. 5), on which the deposition material is deposited, may be formed substantially flat. According to this structure, a gap may be compensated, which may occur between the inorganic layer IOL and the substrate SUB of the display panel DP due to a height difference between the inorganic layer IOL and the pattern layer PL in the third direction as shown in FIG. 2. In other words, the insulating layer IL may cover both the deposition area DA and the non-deposition area NDA of the mask MSK′ for deposition with a same thickness, so that a gap between the mask MSK′ for deposition and the display panel DP may be minimized. Accordingly, a deposition process may be stably performed. Further, the defect rate of the display panel DP may be reduced.

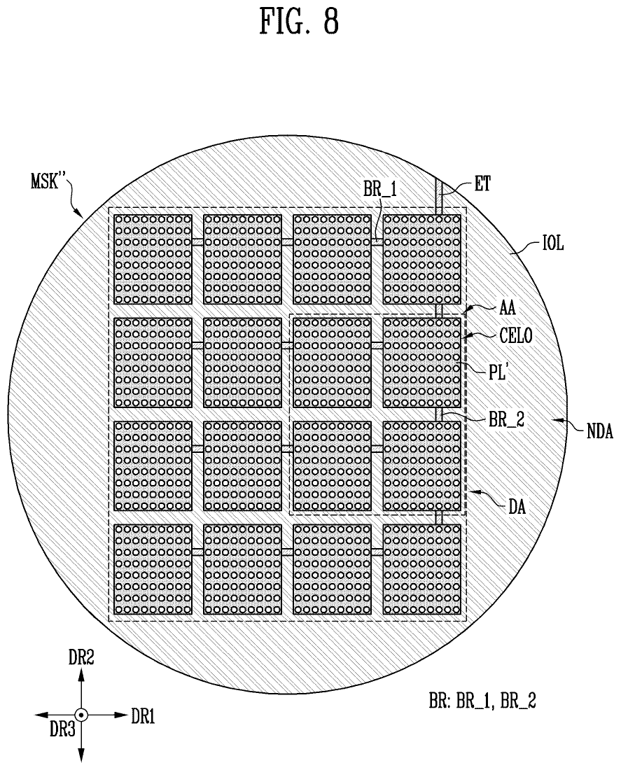

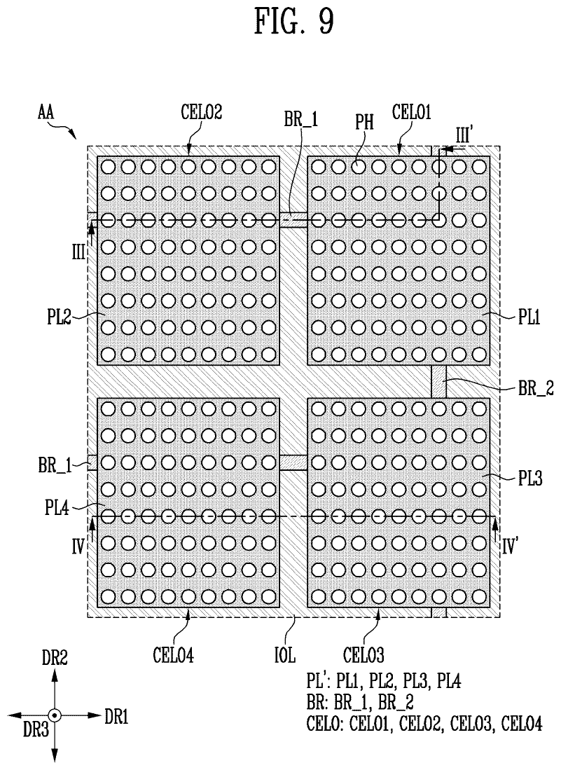

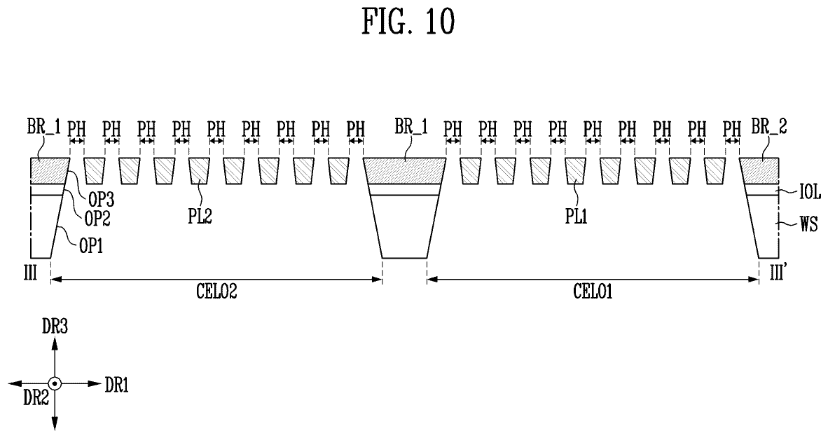

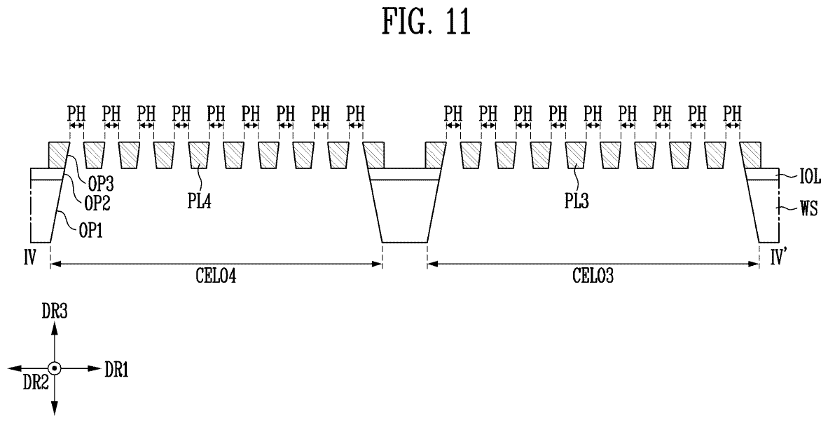

FIG. 8 is a plan view illustrating still another embodiment of the mask for deposition. FIG. 9 is an enlarged plan view of area AA shown in FIG. 8. FIG. 10 is a schematic cross-sectional view taken along line III-III′ shown in FIG. 9. FIG. 11 is a schematic cross-sectional view taken along line IV-IV′ shown in FIG. 9.

Referring to FIGS. 8 to 11, a mask MSK″ for deposition in accordance with an embodiment of the disclosure may include a wafer substrate WS, an inorganic layer IOL, a pattern layer PL′, an electrode terminal ET, and a bridge BR.

The components, i.e., the wafer substrate WS, the inorganic layer IOL, and the electrode terminal ET other than the pattern layer PL′ and the bridge BR, which are shown in FIGS. 6 and 7, may be configured identically to the wafer substrate WS, the inorganic layer IOL, and the electrode terminal ET, which are described with reference to FIGS. 1, 2, 6, and 7. Therefore, hereinafter, overlapping descriptions will be omitted for convenience of description.

Unlike the pattern layer PL formed as one body, which is shown in FIGS. 1, 2, 6, and 7, the pattern layer PL′ may be configured with several pattern layer PL′ blocks each having a size corresponding to one cell opening area CELO. In embodiments, the pattern layer PL′ may include at least one first pattern layer PL1 corresponding to a first cell opening area CELO1, multiple second pattern layers PL2 each corresponding to a second cell opening area CELO2, multiple third pattern layers PL3 each corresponding to a third cell opening area CELO3, and multiple fourth pattern layers PL4 each corresponding to a fourth cell opening area CELO4.

The first pattern layer PL1 may be a pattern layer PL′ block electrically connected to the electrode terminal ET, and may be disposed at an outermost portion of the pattern layer PL′ to be physically connected to the electrode terminal ET. In FIG. 8, it is illustrated that one first pattern layer PL1 is connected to one electrode terminal ET. However, the disclosure is not necessarily limited thereto. For example, the first pattern layer PL1 may correspond to four pattern layers PL′ disposed at corners of a display area DA among multiple pattern layer PL′ blocks shown in FIG. 8. Although not shown in the drawings, four electrode terminals ET may be provided to be respectively connected to first pattern layers PL1. Hereinafter, for convenience of description, an embodiment that one first pattern layer PL1 is provided as shown in FIG. 8 will be described.

The second pattern layers PL2 may be disposed to be spaced part from the first pattern layer PL1 in the first direction DR1.

The third pattern layers PL3 may be disposed to be spaced apart from the first pattern layer PL1 in the second direction DR2.

The fourth pattern layers PL4 may be disposed to be spaced apart from one of the third pattern layers PL3 in the first direction DR1.

The second to fourth pattern layers PL2, PL3, and PL4 may be pattern layer PL′ blocks which are not physically connected to the electrode terminal ET, and may be electrically connected to the first pattern layer PL1 through the bridge BR which will be described below.

The bridge BR may be disposed on the inorganic layer IOL between two of first to fourth pattern layers PL1, PL2, PL3, and PL4 adjacent to each other, to electrically connect a first pattern layer PL1 to other pattern layers PL2, PL3, and PL4.

To this end, the bridge BR may be made of a material having an electrical conductivity, such as a metal, but the disclosure is not necessarily limited thereto. In embodiments, the bridge BR may be formed with the pattern layer PL′ through a same process. Therefore, the bridge BR and the pattern layer PL′ may be made of a substantially same material as. For example, like the pattern layer PL′, the bridge BR may include at least one of silicon (Si), silicon oxide (SiOₓ), silicon nitride (SiNₓ), and silicon oxynitride (SiOₓN_{y}). An impurity may be doped into the bridge BR such that the bridge BR has an electrical conductivity. For example, in case that a Group V element such as phosphorus (P), arsenic (As) or antimony (Sb) is doped into the bridge BR, the bridge BR may have an n-type semiconductor characteristic. For example, in case that a Group III element such as boron (B), gallium (Ga) or indium (In) is doped into the bridge BR, the bridge may have a p-type semiconductor characteristic.

The bridge BR may include multiple first bridges BR_1 and multiple second bridges BR_2.

The first bridges BR_1 may electrically connect, to each other, at least one first pattern layer PL1 and at least one of the second pattern layers PL2, which are arranged in the first direction DR1, and at least one of the third pattern layers PL3 and at least one of the fourth pattern layers PL4, which are arranged in the first direction DR1.

Referring to FIG. 9, a first pattern layer PL1 and a second pattern layer PL2 adjacent to the first pattern layer PL1 in the first direction DR1 may be electrically connected to each other through a first bridge BR_1, and a third pattern layer PL3 and a fourth pattern layer PL4 adjacent to the third pattern layer PL3 in the first direction DR1 may also be electrically connected to each other through a first bridge BR_1. In other words, the first bridge BR_1 may electrically connect pattern layer PL′ blocks arranged in the first direction DR1, i.e., a row direction to each other.

The second bridges BR_2 may electrically connect, to each other, at least one first pattern layer PL1 and at least one of the third pattern layers PL3, which are arranged in the second direction DR2, and at least one of the second pattern layers PL2 and at least one of the fourth pattern layers PL4, which are arranged in the second direction DR2.

Referring to FIG. 9, a first pattern layer PL1 and a third pattern layer PL3 adjacent to the first pattern layer PL1 in the second direction DR2 may be electrically connected to each other through a second bridge BR_2, and a second pattern layer PL2 and a fourth pattern layer PL4 adjacent to the second pattern layer PL2 in the second direction DR2 may be electrically connected to each other through a second bridge BR_2. In other words, the second bridge BR_2 may electrically connect pattern layer PL′ blocks arranged in the second direction DR2, i.e., a column direction to each other.

According to this structure, an external voltage applied to the electrode terminal ET may be applied to the first pattern layer PL1 electrically connected to the electrode terminal ET, and be applied to the second to fourth pattern layers PL2 to PL4 electrically connected to the first pattern layer PL1 through the first and second bridges BR_1 and BR_2. This is because the pattern layer PL′ blocks are disposed to be spaced apart from each other in the first and second directions DR1 and DR2, but have a structure in which the pattern layer PL′ blocks are electrically connected to each other through the first and second bridges BR_1 and BR_2. In case that a positive or negative voltage is applied to the electrode terminal ET during a deposition process, the first to fourth pattern layers PL1, PL2, PL3, and PL4 and the voltage applied to the electrode terminal ET may have a same polarity. During a deposition process, the substrate (see SUB shown in FIG. 5) of the display panel (see DP shown in FIG. 5), which faces the pattern layer PL′, may have a polarity opposite to the polarity of the voltage applied to the electrode terminal ET, and accordingly, an attractive force with which the mask MSK″ for deposition and the substrate SUB of the display panel DP pull each other may act between the mask MSK″ for deposition and the substrate SUB of the display panel DP. Thus, a gap between the mask MSK″ for deposition and the display panel DP may be minimized by the attractive force generated between the mask MSK″ for deposition and the substrate SUB of the display panel DP, and accordingly, the deposition precision of the deposition material may be improved. Further, the defect rate of the display panel DP may be reduced.

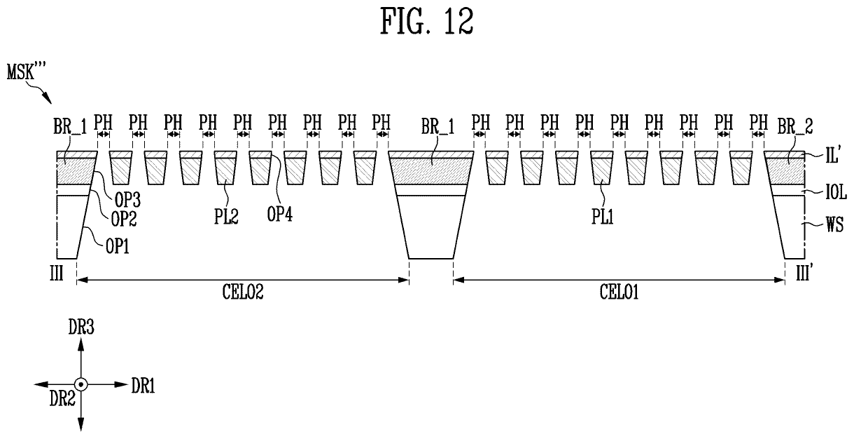

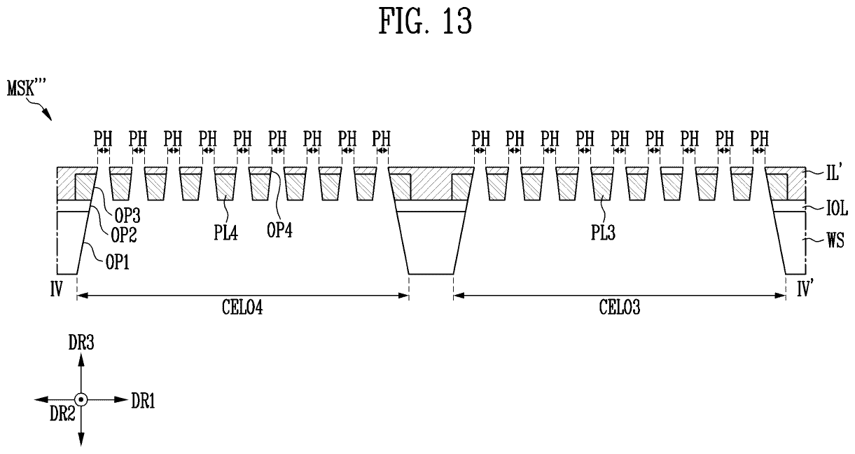

FIG. 12 is a schematic cross-sectional view illustrating another embodiment of FIG. 10. FIG. 13 is a schematic cross-sectional view illustrating another embodiment of FIG. 11.

Referring to FIGS. 12 and 13, a mask MSK″′ for deposition in accordance with an embodiment of the disclosure may include a wafer substrate WS, an inorganic layer IOL, a pattern layer PL′, an electrode terminal ET, and an insulating layer IL′. For convenience of description, a plan view of the pattern layer PL′ is omitted, and second and fourth pattern layers PL2 and PL4 as portions of the pattern layer PL′ are illustrated in FIGS. 12 and 13. Hereinafter, when the “pattern layer PL” is expressed, this means not only the second and fourth pattern layers PL2 and PL4 shown in the drawings but also first and third pattern layers PL1 and PL3 which are not shown in the drawings.

The components, i.e., the wafer substrate WS, the inorganic layer IOL, the pattern layer PL′, and the electrode terminal ET other than the insulating layer IL′ shown in FIGS. 12 and 13 may be configured identically to the wafer substrate WS, the inorganic layer IOL, the pattern layer PL′, and the electrode terminal ET, which are described with reference to FIGS. 8 to 11. Therefore, hereinafter, overlapping descriptions will be omitted for convenience of description.

The insulating layer IL′ may be disposed on the first to fourth pattern layers PL1, PL2, PL3, and PL4, a portion of the inorganic layer IOL, which is disposed between the first to fourth pattern layers PL1, PL2, PL3, and PL4, and a bridge BR in a deposition area DA, and be disposed on another portion of the inorganic layer IOL in a non-deposition area NDA. Like the wafer substrate WS and the inorganic layer IOL, the insulating layer IL′ may have a circular shape in a plan view, and include an insulating material. In embodiments, the insulating layer IL′ may include at least one of an inorganic insulating material and an organic insulating material. For example, the insulating layer IL′ may include an inorganic insulating material such as silicon oxide (SiOₓ), silicon nitride (SiNₓ), or silicon oxynitride (SiOₓN_{y}). For example, the insulating layer IL′ may include an organic insulating material such as an acrylic resin, an epoxy resin, a phenolic resin, a polyamide resin, a polyimide resin, an unsaturated polyester resin, a polyphenylene ether resin, a polyphenylene sulfide resin, or benzocyclobutene (BCB). However, the insulating material constituting the insulating layer IL′ is not necessarily limited to the above-listed materials.

The insulating layer IL′ may include multiple fourth openings OP4 overlapping respective third openings OP3 in the third direction DR3. In embodiments, an inner surface of the insulating layer IL′, which surrounds each of the fourth openings OP4, may have a tapered shape in a cross-sectional view, like an inner surface of the pattern layer PL′, which surrounds each of the third openings OP3. This may be because the fourth openings OP4 are formed by wet-etching the insulating layer IL', but the disclosure is not necessarily limited thereto.

In embodiments, a longest width of any one fourth opening OP4 may be smaller than a longest width of any one third opening OP3 overlapping a corresponding fourth opening OP4 in the third direction DR3. In embodiments, a shortest width of a third opening OP3 may be substantially the same as a longest width of a fourth opening OP4 overlapping the third opening OP3 in the third direction DR3. This means that inner surfaces of a third opening OP3 and a fourth opening OP4, which overlap each other in the third direction DR3, may be successively connected to each other.

As such, multiple fourth openings OP4, multiple third openings OP3 overlapping the fourth openings OP4, and one second opening OP2 and a first opening OP1, which overlap the fourth openings OP4 and the third openings OP3, may be provided in one cell opening area CELO. According to this structure, a deposition material evaporated or sprayed toward the mask MSK″′ for deposition may enter through a first opening OP1 and sequentially pass through a second opening OP2, a third opening OP3, and a fourth opening OP4. A passing path of the deposition material, which is formed by the first to fourth openings OP1, OP2, OP3, and OP4 overlapping each other as described above, may be defined as one pattern hole PH.

In embodiments, the entire top surface of the insulating layer IL′ disposed to face the substrate (see SUB shown in FIG. 5) of the display panel (see DP shown in FIG. 5), on which the deposition material is deposited, may be formed substantially flat. According to this structure, a gap mat be compensated, which may occur between the inorganic layer IOL and the substrate SUB of the display panel DP due to a height difference between the inorganic layer IOL and the pattern layer PL′ in the third direction as shown in FIG. 11. In other words, the insulating layer IL′ may cover both the deposition area DA and the non-deposition area NDA of the mask MSK″′ for deposition with a same thickness, so that a gap between the mask MSK″′ for deposition and the display panel DP may be minimized. Accordingly, a deposition process may be stably performed. Further, the defect rate of the display panel DP may be reduced.

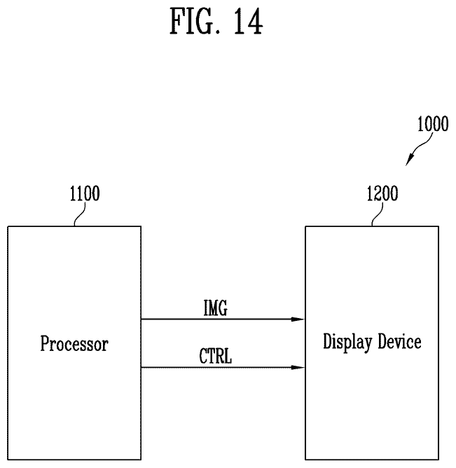

FIG. 14 is a schematic block diagram illustrating an embodiment of a display system.

Referring to FIG. 14, a display system 1000 may include a processor 1100 and a display device 1200.

The processor 1100 may perform various tasks and various calculations. In embodiments, the processor 1100 may include an Application Processor (AP), a Graphics Processing Unit (GPU), a microprocessor, a Central Processing Unit (CPU), and the like. The processor 1100 may be connected to other components of the display system 1000 through a bus system to control the components of the display system 1000.

The processor 1100 may transmit image data IMG and a control signal CTRL to the display device 1200. The display device 1200 may display an image, based on the image data IMG and the control signal CTRL. The display device 1200 may include the display panel DP described with reference to FIG. 4.

The display system 1000 may include a computing system for providing an image display function, such as a smart watch, a mobile phone, a smartphone, a portable computer, a tablet personal computer (PC), a watch phone, an automotive display, a smart glass, a portable multimedia player (PMP), a navigation system, or an ultra mobile computer (UMPC). The display system 1000 may include at least one of a head mounted display (HMD) device, a virtual reality (VR) device, a mixed reality (MR) device, and an augmented reality (AR) device.

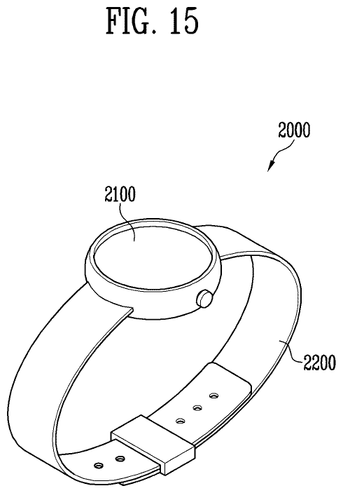

FIGS. 15 to 18 are perspective views illustrating application examples of the display system shown in FIG. 14.

Referring to FIG. 15, the display system 1000 shown in FIG. 14 may be applied to a smart watch 2000 including a display part 2100 and a strap part 2200.

The smart watch 2000 may be a wearable electronic device. For example, the smart watch 2000 may have a structure in which the strap part 2200 may be mounted on a wrist of a user. The display system 1000 and/or the display device 1200 may be applied to the display part 2100, so that image data including time information may be provided to the user.

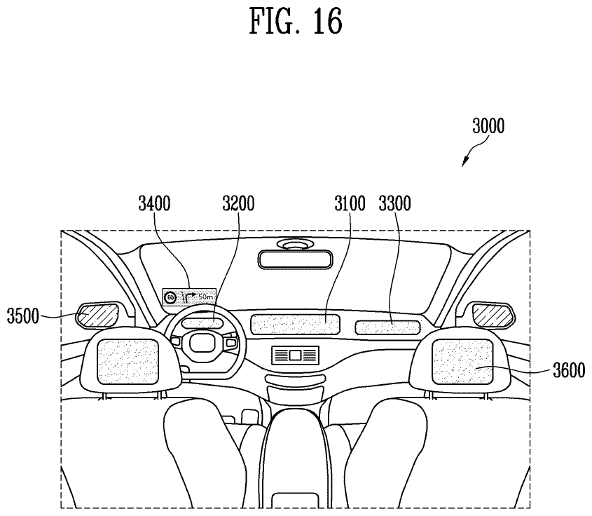

Referring to FIG. 16, the display system 1000 shown in FIG. 14 may be applied to an automotive display system 3000. The automotive display system 3000 may include a computing system provided at the inside/outside of a vehicle to provide image data.

For example, the display system 1000 and/or the display device 1200 may be applied to at least one of an infortainment panel 3100, a cluster 3200, a passenger display 3300, a head-up display 3400, a side mirror display 3500, and a read seat display 3600, which are provided in a vehicle.

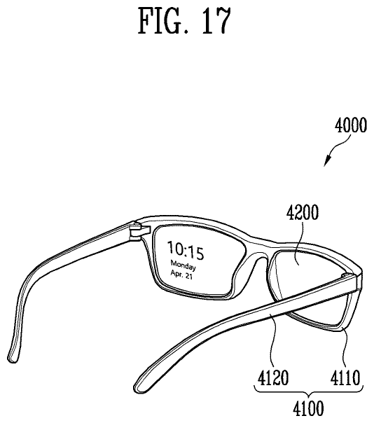

Referring to FIG. 17, the display system 1000 shown in FIG. 14 may be applied to smart glasses 4000. The smart glasses 4000 may be a wearable electronic device which may be worn on the face of a user. For example, the smart glasses 4000 may be a wearable device for Augmented Reality (AR).

The smart glasses 4000 may include a frame 4100 and a lens part 4200. The frame 4100 may include a housing 4110 supporting the lens part 4200 and a leg part 4120 for allowing the user to wear the smart glasses 4000. The leg part 4120 may be connected to the housing 4110 through a hinge, to be folded or unfolded with respect to the housing 4110.

A battery, a touch pad, a microphone, a camera, and the like may be built in the frame 4100. A projector for outputting light, a processor for controlling a light signal, and the like may be built in the frame 4100.

The lens part 4200 may be an optical member which allows light to be transmitted therethrough or allows light to be reflected thereby. For example, the lens part 4200 may include glass, a transparent synthetic resin, and the like.

In order to enable eyes of the user to recognize visual information, the lens part 4200 may reflect an image caused by a light signal transmitted from the projector of the frame 4100 by a rear surface (e.g., a surface in a direction facing the eyes of the user) of the lens part 4200. For example, the user may recognize information including time, data, and the like, which are displayed on the lens part 4200. The projector and/or the lens part 4200 may be a kind of display device. The display device 1200 may be applied to the projector and/or the lens part 4200.

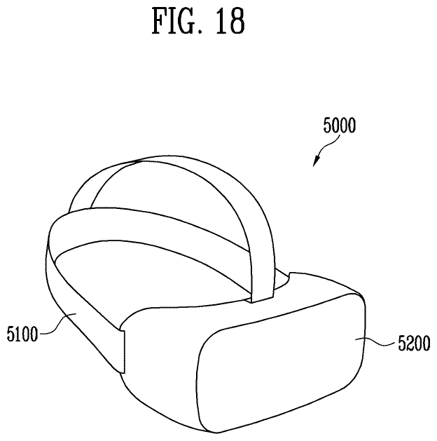

Referring to FIG. 18, the display system 1000 shown in FIG. 14 may be applied to a head mounted display device 5000.

The head mounted display device 5000 may be a wearable electronic device which may be worn on the head of a user. For example, the head mounted display device 5000 may be a wearable device for virtual reality (VR) or mixed reality (MR).

The head mounted display device 5000 may include a head mounted band 5100 and a display accommodating case 5200. The head mounted band 5100 may be connected to the display accommodating case 5200. The head mounted band 5100 may include a horizontal band and/or a vertical band, used to fix the head mounted display device 5000 to the head of the user. The horizontal band may be configured to surround a side portion of the head of the user, and the vertical band may be configured to surround an upper portion of the head of the user. However, the disclosure is not limited thereto. For example, the head mounted band 5100 may be implemented in the form of a glasses frame, a helmet or the like.

The display device accommodating case 5200 may accommodate the display system 1000 and/or the display device 1200.

In the mask for deposition and the display system manufactured by the same in accordance with the disclosure, adhesion with a substrate may be improved, so that deposition failure may be reduced. For example, an electrical characteristic may be applied to a pattern portion of the mask for deposition, so that a gap between the mask for deposition and the substrate may be reduced using an electrostatic force during deposition.

The above description is an example of technical features of the disclosure, and those skilled in the art to which the disclosure pertains will be able to make various modifications and variations. Therefore, the embodiments of the disclosure described above may be implemented separately or in combination with each other.

Therefore, the embodiments disclosed in the disclosure are not intended to limit the technical spirit of the disclosure, but to describe the technical spirit of the disclosure, and the scope of the technical spirit of the disclosure is not limited by these embodiments. The protection scope of the disclosure should be interpreted by the following claims, and it should be interpreted that all technical spirits within the equivalent scope are included in the scope of the disclosure.

What is claimed is:

1. A mask for deposition, which includes a deposition area and a non-deposition area, the mask comprising:
a wafer substrate including a plurality of first openings spaced apart from each other;
an inorganic layer disposed on the wafer substrate and including a plurality of second openings each overlapping with a corresponding one of the plurality of first openings in a plan view;
a pattern layer disposed on the inorganic layer, doped with an impurity to have an electrical conductivity, and including a plurality of third openings overlapping one of the plurality of first openings and one of the plurality of second openings, which overlap with each other in a plan view; and
at least one electrode terminal electrically connected to the pattern layer to apply an external voltage to the pattern layer, wherein
the wafer substrate and the inorganic layer are formed in the deposition area and the non-deposition area,
the pattern layer is formed in the deposition area, and
the at least one electrode terminal is formed in the non-deposition area.

2. The mask of claim 1, wherein the wafer substrate includes monocrystalline or polycrystalline silicon.

3. The mask of claim 1, wherein
the inorganic layer includes at least one of silicon oxide (SiOₓ), silicon nitride (SiNₓ), and silicon oxynitride (SiOₓN_{y}),
x is a rational number, and
y is another rational number.

4. The mask of claim 1, wherein
the pattern layer includes at least one of silicon (Si), silicon oxide (SiOₓ), silicon nitride (SiNₓ), and silicon oxynitride (SiOₓN_{y}),
x is a rational number, and
y is another rational number.

5. The mask of claim 1, wherein the at least one electrode terminal is made of a material having an electrical conductivity.

6. The mask of claim 1, wherein the at least one electrode terminal and the pattern layer are made of a substantially same material.

7. The mask of claim 1, wherein
one of the plurality of first openings, one of the plurality of second openings, and the plurality of third openings, which overlap each other in a plan view, form a cell opening area, and
the cell opening area defines a display area of a display panel.

8. The mask of claim 1, wherein the pattern layer is formed as one body in an entire area of the deposition area.

9. The mask of claim 1, further comprising:
an insulating layer disposed on the pattern layer in the deposition area, disposed on the inorganic layer in the non-deposition area, and including a plurality of fourth openings each overlapping with a corresponding one of the plurality of third openings in a plan view.

10. The mask of claim 9, wherein an entire top surface of the insulating layer, which faces a substrate on which a deposition material is deposited, is formed substantially flat.

11. The mask of claim 9, wherein the insulating layer includes at least one of an inorganic insulating material and an organic insulating material.

12. The mask of claim 1, wherein
the pattern layer includes:
at least one first pattern layer electrically connected to the at least one electrode terminal;
a plurality of second pattern layers spaced apart from the at least one first pattern layer in a first direction;
a plurality of third pattern layers spaced apart from the at least one first pattern layer in a second direction intersecting the first direction; and
a plurality of fourth pattern layers spaced apart from one of the plurality of third pattern layers in the first direction, and
the mask further comprises a bridge electrically connecting the at least one first pattern layer to the plurality of second pattern layers, the plurality of third pattern layers, and the plurality of fourth pattern layers.

13. The mask of claim 12, wherein the external voltage applied to the at least one first pattern layer through the at least one electrode terminal is applied to the plurality of second pattern layers, the plurality of third pattern layers, and the plurality of fourth pattern layers through the bridge.

14. The mask of claim 12, wherein the bridge and the pattern layer are made of a substantially same material.

15. The mask of claim 12, wherein the bridge is disposed on the inorganic layer between adjacent ones of the at least one first pattern layer, the plurality of second pattern layers, the plurality of third pattern layers, and the plurality of fourth pattern layers.

16. The mask of claim 12, wherein the bridge includes:
a plurality of first bridges electrically connecting, to each other, the at least one first pattern layer and at least one of the plurality of second pattern layers, which are arranged in the first direction, and at least one of the plurality of third pattern layers and at least one of the plurality of fourth pattern layers, which are arranged in the first direction; and
a plurality of second bridges electrically connecting, to each other, the at least one first pattern layer and at least one of the plurality of third pattern layers, which are arranged in the second direction, and at least one of the plurality of second pattern layers and at least one of the plurality of fourth pattern layers, which are arranged in the second direction.

17. The mask of claim 12, further comprising:
an insulating layer disposed on the at least one first pattern layer, the plurality of second pattern layers, the plurality of third pattern layers, and the plurality of fourth pattern layers, a portion of the inorganic layer, which is disposed between the at least one first pattern layer, the plurality of second pattern layers, the plurality of third pattern layers, and the plurality of fourth pattern layers, and the bridge in the deposition area, disposed on another portion of the inorganic layer in the non-deposition area, and including a plurality of fourth openings each overlapping with a corresponding one of the plurality of third openings in a plan view.

18. The mask of claim 17, wherein an entire top surface of the insulating layer, which faces a substrate on which a deposition material is deposited, is formed substantially flat.

19. A display system comprising:
an organic light emitting layer disposed between a cathode electrode and an anode electrode,
wherein the organic light emitting layer is formed by the mask of claim 1.
